(19) United States
(12) Patent Application Publication
(10) Pub. No.: US 2015/0084152 A1
(43) Pub. Date: Mar. 26, 2015

(54) PHOTODIODE

(71) Applicants: YUN-SHAN CHANG, SAN JOSE, CA (US); DA WEI LIN, NEW TAIPEI CITY (TW)

(72) Inventor: YUN-SHAN CHANG, SAN JOSE, CA (US)

(73) Assignees: Da Wei Lin, New Taipei City (TW); Yun-Shan Chang, San Jose, CA (US)

(21) Appl. No.: 14/034,805

(22) Filed: Sep. 24, 2013

(51) Int. Cl. H01L 31/0352

(52) U.S. Cl. CPC H01L 31/035272
USPC 257/463

(57) ABSTRACT

A photodiode includes a first-type substrate. A second-type doped well and a second-type doped region are formed in the first-type substrate. An isolation region is formed to enclose the peripheral side of the second-type doped well, and separated from the second-type doped well. The second-type doped region is formed in the second-type doped well and extends from the surface of the second-type doped well. A protective layer covers the first-type substrate. A contact conductor including a contact layer and a conductive strip penetrates through the protective layer. The contact layer is formed on the bottom end of the conductive strip and in contact with the second-type doped region to make an electrical connection.

### BACKGROUND OF THE INVENTION

1. Field of the Invention

The present invention relates to an image sensor; in particular, to a photodiode image sensor.

2. Description of Related Art

Complementary metal-oxide-semiconductor (CMOS) image sensor includes an active pixel matrix or an image sensor cell array. The conventional image sensor cell includes a photodiode for sensing the intensity of the illumination and transforming the received optical signal into digital signal. The digital signal may be then received by the transistor arranged adjacently to the image sensor cell.

The abovementioned transistor as well as the other additional devices arranged in the peripheral region, such as the control and signal processing circuits and the logic circuit and so on, are integrated to be a photodiode-type CMOS image sensor. In order to reduce the cost and simplify the manufacturing processes, each of steps for manufacturing the circuits arranged in the peripheral region of the photodiode-type CMOS image sensor is also used to form the transistor arranged in the main region so that the circuit and the photodiode-type CMOS image sensor are fabricated in the same processing step.

However, the abovementioned fabricating method usually results in unfavorable effect on the electrical properties of the image sensor cell configured in the main region for sensing light. Specifically, the recombination centers may be generated due to the Si dangling bond defects at the interface between the semiconductor and the oxide, and thus reducing the lifetime of the minority carrier and generating the leakage current. In addition, the silicide (self-aligned silicidation) is formed in the peripheral region to be serve as the electrodes, for example, the gate, source and drain electrodes of the CMOS logic circuit, in the meanwhile, the silicide is also formed on the surface of the photodiode, and the impact resulted from the abovementioned defects may be reinforced. As a result, the dark current in the image sensor cell may increase, and the signal-to-noise ratio (SNR) would be decreased, which impact the sensitivity of the image sensor.

As the semiconductor processing techniques are developed, the demands for minimizing the device and precisely controlling the fabrication of the CMOS device may be satisfied. However, the smaller the distance between the devices, the more obvious the interference between the devices. As the result, the fabrication of the shallow trench isolation (STI) between the devices becomes more and more important. In the structure of the conventional photodiode, the defects existing between the isolating layer enclosing the photodiode and the active region may lead to the occurrence of the dark current, so does the Si dangling bond defects existing in the portion of the side region of the photodiode or near to the surface of the Si substrate. That is to say, according to the surface physics, there are dangling bonds formed at the interface between the isolating layer and the active region. As a result, when the carriers drift to the interface, some of the carriers would be trapped and released at certain energy level randomly. It may lead to the generation of the dark current which may result in the worse image quality captured by the image sensor and smaller dynamic range.

### SUMMARY OF THE INVENTION

The object of the present invention is to decrease the leakage current, which results from lattice mismatch at the interface between the isolating layer and the N-well in conventional photodiode. The lattice mismatch is caused by a strain which may result from a difference in coefficient of thermal expansion between the isolating layer and the n-well or generated while fabricating the isolating layer.

In order to achieve the aforementioned objects, according to an embodiment of the present invention, a photodiode, the isolating layer and the n-well of which are separated by a distance, is provided.

The photodiode includes a first-type substrate. A second-type doped well is formed within the first-type substrate. A second-type doped region is formed within the second-type doped well. In the first-type substrate, an isolation region is formed to act as an isolation device in the photodiode, and separated from the second-type doped well. A protective layer is formed on the upper surface of the first-type substrate to cover the second-type doped well. A contact conductor penetrates through the protective layer and includes a contact layer and a conductive strip. The contact layer is formed on a bottom end of the conductive strip, and in contact with the second-type doped region to make electrical connection.

Compare to the conventional photodiode, the isolation region is separated from the second-type doped well in the photodiode of the instant disclosure. As a result, the defects at the interface between the isolation region and the first-type substrate are also separated from the active region by a distance, and the interference of the dark current for the active region may be avoid.

In order to further the understanding regarding the present invention, the following embodiments are provided along with illustrations to facilitate the disclosure of the present invention.

### BRIEF DESCRIPTION OF THE DRAWINGS

FIG. 1 shows a top view of a photodiode according to an embodiment of the instant disclosure;

FIG. 2 shows a cross-sectional view of the photodiode taken along a line A-A shown in FIG. 1;

FIG. 3 shows a cross-sectional view of a photodiode according to an embodiment of the instant disclosure; and

FIG. 4 shows a cross-sectional view of a photodiode according to an embodiment of the instant disclosure

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

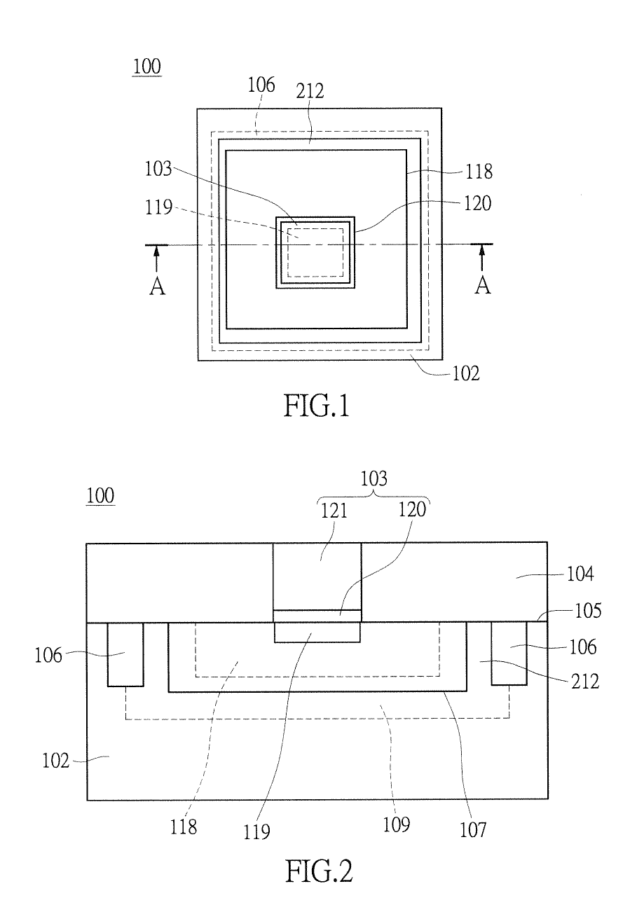

Please refer to FIG. 1 and FIG. 2. FIG. 1 shows a top view of photodiode according to an embodiment of the instant disclosure, and FIG. 2 shows a cross-sectional view of the photodiode taken along a line A-A shown in FIG. 1. The photodiode 100 of the instant disclosure includes a first-type substrate 102, a second-type doped well 118, a second-type doped region 119, a depletion region 109, a P-N junction 107, an isolation region 106, a contact layer 120, a contact conductor 103 and a protective layer 104. The first-type substrate 102 has an upper surface 105 for receiving the light. The second-type doped well 118 is defined within the first-type substrate 102 for doping the impurities, and the P-N junction 107 is formed between the first-type substrate 102 and second-type doped well 118. The second-type doped region 119 is defined within the second-type doped well 118 and is doped by the same type impurities, which extends from a surface layer to the bulk of the second-type doped well 118.

In one embodiment, the abovementioned first-type substrate 102 is P-substrate, and the second-type doped well 118 is N-well. The second-type doped region 119 is N-type doped region defined within the second-type doped well 118, and has higher concentration of the donor impurities than that of the second-type doped well 118.

The abovementioned depletion region 109, the region enclosed by the break line shown in FIG. 2, is defined by a peripheral region of the P-N junction 107 between the first-type substrate 102 and the second-type doped well 118.

The isolation region 106, which act as an isolating structure of the photodiode 100, is formed in the abovementioned first-type substrate 102 and separated from the second-type doped well 118. Specifically, there is a space 212 between the isolation region 106 and second-type doped region 119 in the instant disclosure. The space 212 is a partial region of the depletion region 109, of course, the structure of the space 212 is the same as that of the depletion region 109. In accordance with the embodiment of the instant disclosure, the isolation region 106 of which is separated from the second-type doped region 119. In other words, the isolation region 106 may not be in contact with the P-N junction 107 between the first-type substrate 102 and second-type doped well 118. The isolation region 106 also limits the range of the depletion region 109 at the lateral side. The isolation region 106 may be made of silicon nitride (Si₃N₄) or silicon dioxide (SiO₂), and fabricated by the process of the local oxidation of silicon (LOCOS), shallow trench isolation (STI) and field oxide, and so forth.

The protective layer 104 is formed on an upper surface 105 of the abovementioned first-type substrate 102, and covers the second-type doped well 118. In addition, the contact conductor 103 is formed on the upper surface 105 of the first-type substrate 102, and covers the second-type doped region 119. For example, the contact conductor 103 is a contact plug. In one embodiment, the contact conductor 103 includes a contact layer 120 and a conductive strip 121. The conductive strip 121 is formed on the contact layer 120. Specifically, the protective layer 104 has an opening (not labeled) to expose the second-type doped region 119, and the contact layer 120 and the conductive strip 121 are formed on the second-type doped region 119 through the opening. In other words, the contact layer 120 is electrically connected to and in contact with the second-type doped region 119 through the opening.

The protective layer 104 is made of an insulating transparent material, such as epoxy. When a light irradiate on the upper surface 105 of the second-type doped well 118, and the energy of the photons would be absorbed so that a plurality of the electron-hole pairs is generated in the depletion region 109. Each of the electron-hole pairs is separated into electrons and holes by photovoltaic effect, and then a current is generated. The generated current can be collected and flow to CMOS circuit through the contact conductor 103 disposed on the second-type doped region 119.

Please refer to FIG. 2. The abovementioned isolation region 106 and the second-type doped region 119 are separated from each other by the space 212. In one embodiment, the space 212 has a width of larger than 50 μm. While the isolation region 106 is fabricated by the processes, such as etching, chemical mechanical polishing (CMP), low pressure chemical vapor deposition system, and so on, the lattice structure of the first-type substrate 102 at the interface between the first-type substrate 102 and the isolation region 106 would be damaged by a mechanical stress, and leading to the formation of the defects, such as dislocation. Since the isolation region 106 may not overlap the second-type doped well 118, these defects at the interface is far from the second-type doped well 118, and the leakage current near to the second-type doped well 118 may be decreased.

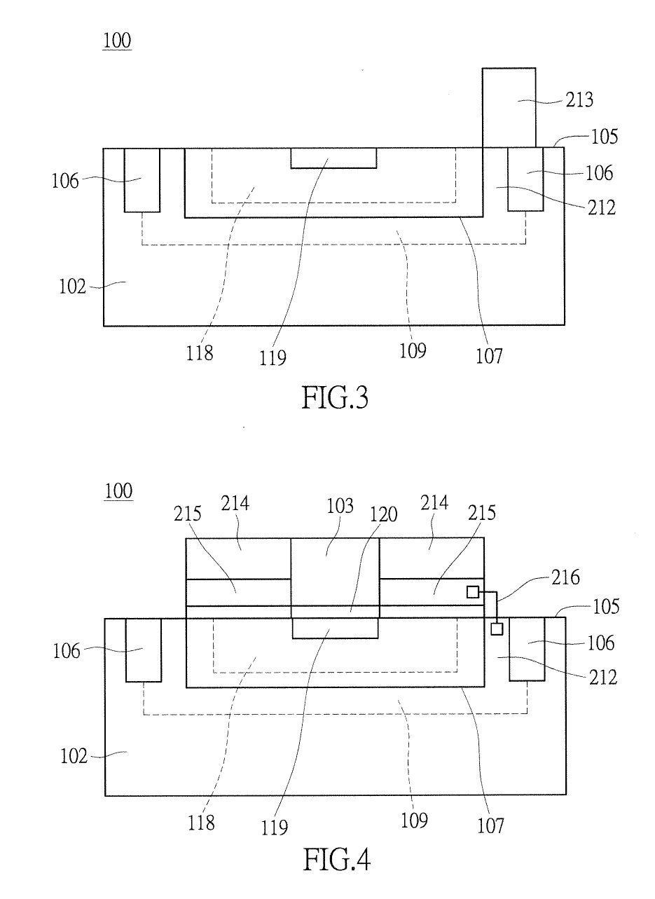

Please refer to FIG. 3, which illustrates a cross-sectional view of a photodiode and for explanation of the formation of the space shown in FIG. 2. In one embodiment of the instant disclosure, after forming the isolation region 106 within the first-type substrate 102 and before ion implantation, a passivation layer 213 is formed on the upper surface 105 of the first-type substrate 102. The passivation layer 213 superimposing on the space 212 and the isolation region 106 can be serve as a mask for the following ion implantation to prevent the impurities from doping into the space 212 between the isolation region 106 and the second-type doped region 119. As a result, the impurities may be blocked by the passivation layer 213 during ion implantation, and may not diffuse into the isolation region 106. The leakage current at the interface between the isolation region 106 and the second-type doped region 119 may be decreased.

Please refer to FIG. 2. In this embodiment of the instant disclosure, a photodiode 100 is provided. The protective layer 104 is formed on the upper surface 105 of the first-type substrate 102. The protective layer 104 covers the second-type doped well 118. The contact conductor 103 includes the contact layer 120 and the conductive strip 121, and the contact layer 120 is formed on a bottom end of the conductive strip 121. When the contact conductor 103 penetrates through the protective layer 104, the contact conductor 103 is connected to and in contact with the second-type doped region 119 by the contact layer 120.

The abovementioned contact layer 120 is a silicide layer which is fabricated by self-aligned silicidation. Various kinds of metals or alloys can be chose to form the silicide. For example, the metal is Ti, Co, Ni, Pd, Pt, and the alloy is Ti/W, Ti/Mo, Co/W or Co/Mo.

The silicide at the surface of the photodiode 100 may become an origin which may induce the leakage current or induce the formation of the recombination center at the surface, thus leading to less photocurrent collection. In one embodiment of the instant disclosure, in the photodiode 100, a covering range of the contact layer 120 is limited within a bottom area of the conductive strip 121, where the bottom area faces to the upper surface 105. A portion of the contact layer 120 formed on the surface of the photodiode 100 and not covered by the conductive strip 121 may be removed. In other words, in the top view, the silicide (the portion of the contact layer 120) extending out of the range covered by the conductive strip 121 would be removed to attenuate the effect of the portion of the contact layer 120 on leakage current.

In addition, the absorption depth of the incident light in the photodiode depends on the wavelength of the incident light. When the incident light penetrates the photodiode, if the incident light with shorter wavelength, it would be absorbed near the surface layer of the photodiode, whereas the incident light with longer wavelength would more deeply penetrate into the photodiode, i.e., the incident light with longer wavelength has deeper absorption depth. The photodiode-type CMOS image sensor has a good sensitivity for the infrared light, which has the wavelength ranging between 700 nm to 800 nm in the light spectrum. In addition, the photodiode-type CMOS image sensor has grater quantum efficiency when irradiated by the incident light having wavelength of 850 nm. Moreover, the spectral response of the photodiode-type CMOS image sensor to incident light rises as the wavelength increasing in a spectral response curve. Because the incident light with longer wavelength has deeper penetration length, the photons in the incident light may penetrate into the P-N junction 107 and transfer their energy to electrons. After absorbing the energy of the photons, the electron-hole pairs at the P-N junction 107 may be generated and decoupled by the internal electric-field of the P-N junctions, thus, the transformation efficiency at the P-N junction 107 is higher. When the incident light has shorter wavelength, the energy of the incident light is absorbed at the surface layer, there are more recombination centers at which than in the body, the generated electron-hole pairs are easily recombined again, and thus decreasing the responsivity. However, for the photodiode for detecting the infrared light or the light with longer wavelength, if the photodiode absorbs the light with shorter wavelength, for example, blue light, the electron-hole pairs generated by the blue light at the surface layer may result in the noise, and affect the sensitivity of the photodiode.

In one embodiment of the instant disclosure, for the photodiode 100 for majorly sensing the infrared light, the structure of the protective layer 104 is adjusted. Please refer to FIG. 4. The protective layer 104 is formed from a stack including a transparent conductive oxide layer 214 and a polysilicon layer 215. In one example, the transparent conductive oxide layer 214 is disposed on the polysilicon layer 215. In one embodiment, the polysilicon has a thickness of 0.1 μm. The polysilicon layer 215 and the transparent conductive oxide layer 214 are electrically connected to the first-type substrate 102. The polysilicon layer 215 is connected to ground by an electrode 216. When the incident light with short wavelength irradiates the photodiode, before penetrating into the first-type substrate 102, the incident light is absorbed within the transparent conductive oxide layer 214 or in the polysilicon layer 215. A photoelectric current generated in the transparent conductive oxide layer 214 or in the polysilicon layer 215 is leaded to ground through the electrode 216. The arrangement of the transparent conductive oxide layer 214 and the polysilicon layer 215 can assist to filter the stray light with shorter wavelength.

The abovementioned transparent conductive oxide layer 214 is made of conductive metal oxide. In one preferred example, the conductive metal oxide is indium tin oxide (ITO).

The polysilicon layer 215 is formed on the upper surface 105 of the first-type substrate 102, and encloses the contact conductor 103. The transparent conductive oxide layer 214 superimposes on the polysilicon layer 215. The arrangement of the polysilicon layer 215 can make the peak concentration of the second-type doped well 118 move deeper into the first-type substrate 102 and create an absorption tail structure to enhance the absorption efficiency.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A photodiode comprising:
a first-type substrate having an upper surface;
a second-type doped well defined within the first-type substrate, wherein a P-N junction is formed at an interface between the first-type substrate and the second-type doped well;
a second-type doped region defined within the second-type doped well and extending from a surface of the second-type doped well;
an isolation region formed within the first-type substrate and separated from the second-type doped well;
a protective layer formed on the upper surface and covering the second-type doped well; and
a contact conductor penetrating through the protective layer and including a contact layer and a conductive strip, wherein the conductive strip is formed on the contact layer, and the contact layer is connected to and in contact with the second-type doped region.

2. The photodiode according to claim 1, wherein the first-type substrate is a P-substrate.

3. The photodiode according to claim 1, wherein the second-type doped well has a relative low doping concentration, and the second-type doped region has a relative high doping concentration.

4. The photodiode according to claim 1, wherein the contact layer is fabricated by a self-aligned silicidation.

5. The photodiode according to claim 1, wherein the isolation region is made of silicon dioxide or silicon nitride.

6. The photodiode according to claim 1, wherein the isolation region is fabricated by local oxidation of silicon (LOCOS), shallow trench isolation (STI) or field oxidation (FOX).

7. The photodiode according to claim 1, wherein the protective layer comprising a transparent conductive oxide layer and a polysilicon layer, wherein the transparent conductive oxide layer is stacked on the polysilicon layer.

8. The photodiode according to claim 7, wherein the polysilicon layer has a thickness of 0.1 μm.

9. The photodiode according to claim 7, wherein the polysilicon layer is electrical connected to the first-type substrate.

10. The photodiode according to claim 1, wherein the contact conductor is a contact plug.
